(19) United States
(12) Patent Application Publication
(10) Pub. No.: US 2018/0095139 A1
(43) Pub. Date: Apr. 5, 2018

(54) PASSIVE PROPAGATION TEST FIXTURE

(71) Applicant: Faraday&Future Inc., Gardena, CA (US)

(72) Inventors: Kameron Fraige Saad Buckhout, SR., Inglewood, CA (US); William Clarke Eberts, Los Angeles, CA (US); Andrew J. Shiraki, Huntington Beach, CA (US)

(21) Appl. No.: 15/283,198

(22) Filed: Sep. 30, 2016

(51) Int. Cl. G01R 31/36; H01M 10/42

(52) U.S. Cl. CPC G01R 31/3658; H01M 10/4285

(57) ABSTRACT

Certain embodiments are described that provide a battery cell testing fixture. The fixture has a first test housing shaped to hold a plurality of battery cells including a central battery cell and a plurality of surrounding battery cells. The first test housing holds the plurality of battery cells in a desired proximity corresponding to an actual proximity in a production battery cell module containing a lamer number of battery cells. At least one battery test initiation lead element is configured to be engaged to the central battery cell. At least one battery test monitoring lead element configured to be engaged to one of the plurality of surrounding battery cells.

### BACKGROUND

Aspects of the disclosure relate to testing battery cells in a module, in particular for thermal runaway effects or other testing that may damage the battery cell.

Thermal runaway in a group of battery cells occurs when overheating of one or more battery cells leads to overheating of neighboring battery cell(s), and positive feedback results a runaway condition that affects an ever increasing number of cells. Thermal runaway can quickly overwhelm the thermal management system put in place to regulate the operating temperature of the battery cells and lead to catastrophic failure. Thus, testing of the thermal runaway properties of battery cells and their configurations is critically important. However, thermal runaway testing is generally destructive in nature and usually involves the use of production battery modules, which can include a large number of battery cells (e.g., up to hundreds of cells). As a result, thermal runaway testing can be expensive and time consuming. There is a need for a more efficient and cost effective system for testing thermal runaway conditions.

### SUMMARY

Certain embodiments are described that provide a battery cell testing fixture and method for using the fixture. The fixture has a first test housing shaped to hold a plurality of battery cells including a central battery cell and a plurality of surrounding battery cells. The first test housing holds the plurality of battery cells in a desired proximity corresponding to an actual proximity in a production battery module containing a larger number of battery cells. At least one battery test initiation lead element is configured to be engaged to the central battery cell. At least one battery test monitoring lead element configured to be engaged to one of the plurality of surrounding battery cells. In one embodiment, thermocouples are attached to all battery cells.

In one embodiment, the first test housing has an endplate portion having depressions for engaging ends of the plurality of battery cells and maintaining the plurality of battery cells in the desired proximity. The first test housing is adjusted to the desired testing temperature with a thermally conductive fluid and includes a fluid inlet port and a fluid outlet port. The fluid inlet port is proximate a first end of the first test housing, and the fluid outlet port is proximate a second end of the first test housing. The first test housing is configured to be sealed to hold a fluid during testing.

### BRIEF DESCRIPTION OF THE DRAWINGS

Aspects of the disclosure are illustrated by way of example. In the accompanying figures, like reference numbers indicate similar elements.

FIG. 1 shows an exploded, perspective view of an embodiment of a fluid fillable test fixture;

FIG. 2 is a diagram illustrating a perspective view of the assembled test fixture of FIG. 1 according to an embodiment;

FIG. 3 shows an embodiment of a central separator plate in the embodiment of FIG. 1;

FIG. 4 shows an embodiment of the battery cells inserted into the embodiment of FIG. 3;

FIG. 5 shows an embodiment of a cover plate on the embodiment of FIG. 4:

FIG. 6 shows an embodiment of a test fixture and a cooling plate;

FIG. 7 shows an embodiment of the test fixture of FIG. 6 before attachment to the cooling plate;

FIG. 8 shows a top view of an embodiment of a fluid fillable test fixture including an outer ring of plugs instead of battery cells, showing the battery cells and plugs inside the test fixture;

FIG. 9 is an exploded, perspective view of the test fixture in the embodiment of FIG. 8;

FIG. 10 is a top view of one embodiment of an interior end cap interior plate of the test fixture of FIG. 9;

FIG. 11 is a top view of one embodiment of an exterior end cap of the test fixture of FIG. 9;

FIG. 12 is a perspective view of an assembled test fixture of the embodiment of FIG. 9;

FIG. 13 is a perspective view of the assembled test fixture of the embodiment of FIG. 12 before inserting the battery cells and plates;

FIG. 14 is a perspective view of the assembled test fixture of the embodiment of FIG. 12 with the exterior end cap added;

FIG. 15 is a diagram of an embodiment of a test system for the test fixture of the above embodiments; and

FIG. 16 illustrates an example of a computing system in which one or more embodiments may be implemented.

### DETAILED DESCRIPTION

Examples are described herein in the context of testing battery cells in a module. Those of ordinary skill in the art will realize that the following description is illustrative only and is not intended to be in any way limiting. Reference will now be made in detail to implementations of examples as illustrated in the accompanying drawings. The same reference indicators will be used throughout the drawings and the following description to refer to the same or like items.

In the interest of clarity, not all of the routine features of the examples described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another.

### Fluid Filled Embodiment

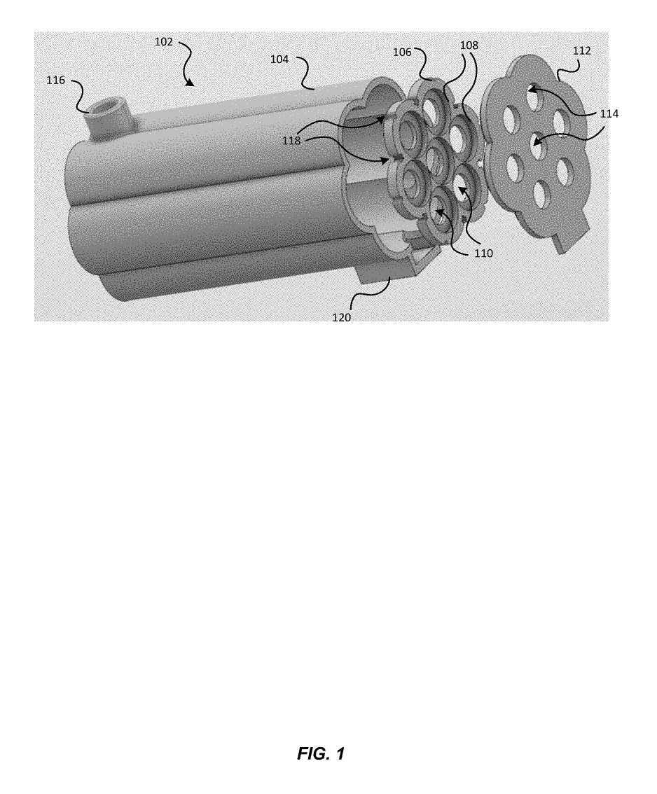

FIG. 1 shows an exploded, perspective view of an embodiment of a fluid filled test fixture 102. A housing 104 holds 14 cylindrical battery cells. A group of 7 battery cells, with a center battery cell and 6 surrounding battery cells, form a cluster of 7 cells. Two 7-cell clusters are inserted back-to-back in housing 104. One half of the test fixture is the “mirror image” of the other half of the text fixture. The two clusters of cells are placed “back-to-back.” An internal plate 106 is inserted into the housing 104 to hold the cluster of cells in place. Depressions 108 hold the bottom ends of a cluster of seven battery cells. An internal end plate 112 seals off the end of the fixture housing 104. Openings 114 provide access to the top caps of the cells (to check wiring, inject epoxy, etc). These openings 114 are sealed off (e.g., with epoxy) prior to testing.

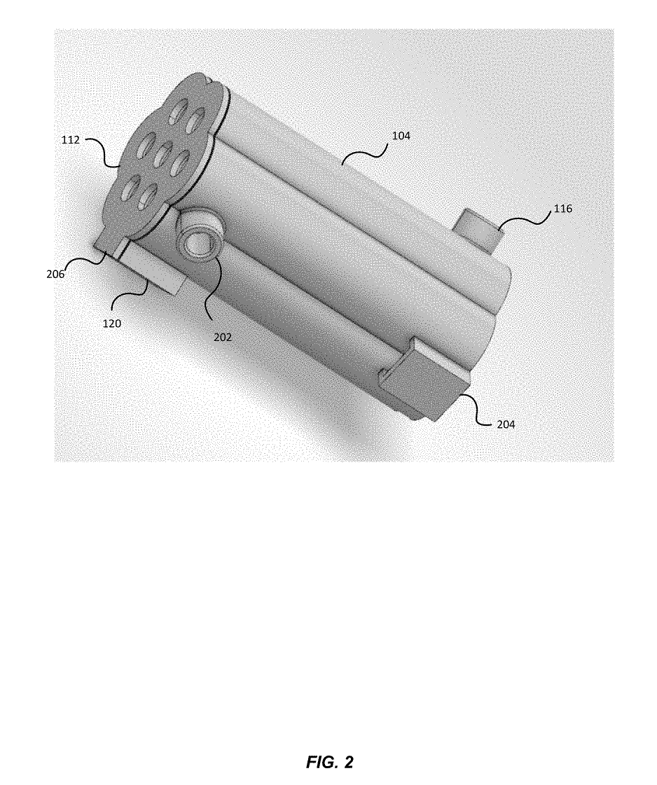

A thermally conductive fluid is provided to the battery cells through an inlet 116, and exits through an outlet (not visible in this view—outlet 202 in FIG. 2). The fluid can pass through central separator plate 106 through gaps 118. The fluid is used to adjust the battery cells to the desired testing temperature, typically using a heated fluid.

A wiring feed-through box 120 provides access for wires to connect to the battery cells. One wire is used to excite the center battery cell to thermal runaway, by overcharging, short-circuiting, faking an internal short, or other techniques. Other wires connect to thermocouples for measuring the heat of the various battery cells. The wires can also conned to cells to sense voltage. In some embodiments other sensors may be used. Once assembled, box 120 is filled with epoxy or another material to make housing 104 fluid tight.

FIG. 2 is a diagram illustrating a perspective view of the assembled text fixture of FIG. 1 according to an embodiment. In addition to the elements from FIG. 1, this view shows the fluid outlet 202 and a second wiring box 204. This view also shows how tab 206 of end plate 112 seals the end of wiring box 120. As can be seen, the fluid inlet 116 and outlet 202 are proximate opposite ends of housing 104 to facilitate fluid flow throughout the module, and to simulate the fluid flow in a production battery module having hundreds of battery cells. In one embodiment, testing is done with “passive propagation” (a.k.a. “static fluid”). That is, the test fixture is filled with fluid first, then the fluid flow is cut off prior to starting the test. Thus, during testing, there is no fluid flowing into and out of the text fixture.

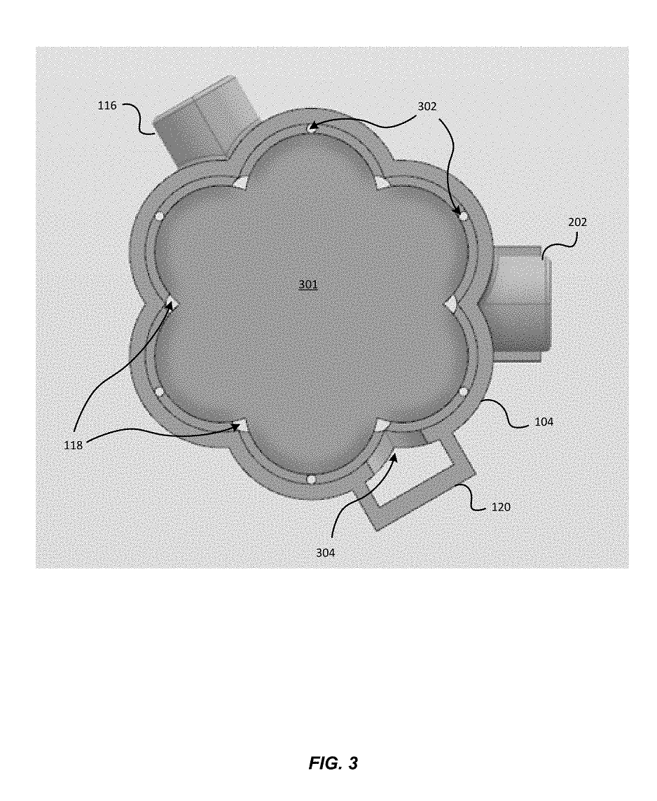

FIG. 3 shows an embodiment of a central separator plate in the embodiment of FIG. 1. A solid plate 301 is shown in this embodiment, rather the embodiment with openings for the battery cell terminals. In addition to fluid flow openings 118 shown in FIG. 1, additional holes 302 for fluid flow are provided. This view also shows a notch 304 inside wiring box 120, which provides an access channel for wiring to reach the battery cells inside housing 104.

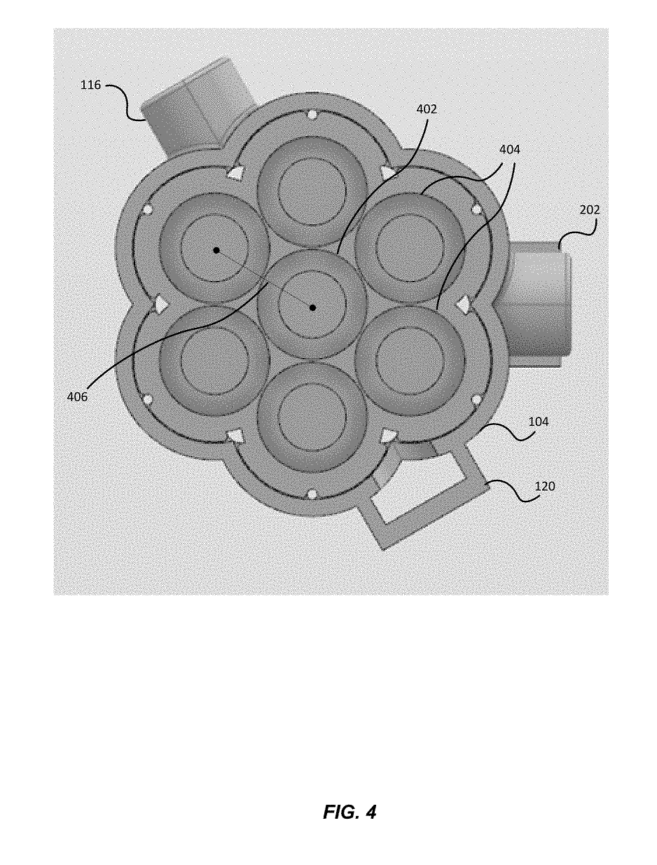

FIG. 4 shows an embodiment of the battery cells inserted into the embodiment of FIG. 3. A center cylindrical battery cell is provided, surrounded by 6 battery cells. FIG. 3 shows the cell ducts of the inserted cells, with a cell duct 402 for the center battery cell and cell ducts 404 for the surrounding battery cells. The battery cells are placed in the same proximity as in a production battery module. One measure of the proximity of cells to one another is referred to as the “pitch” 406, which is the distance from the center of one cell to the center of another.

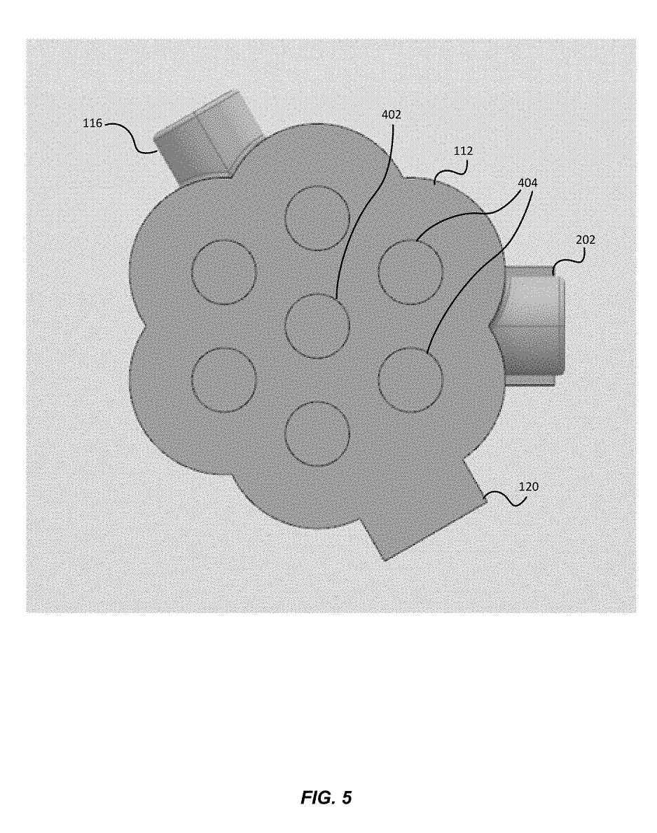

FIG. 5 shows an embodiment of a cover plate 112 in the embodiment of FIG. 4, showing the holes 402 and 404 of the end plates.

In one embodiment, housing 104 and the plates are made of a plastic which has similar heat transfer characteristics to the plastics of a battery module. The plastic components can be manufactured using 3D printing, injection molding, or other techniques. In an alternate embodiment, the housing can he metal. Since metal has a higher heat transfer coefficient, and would wick away more heat than the surrounding battery cells to be modeled, a plastic insert is added to give the desired heat transfer characteristics. The insert (not shown) is shaped the same as the housing in one embodiment. Alternately, the housing can be cylindrical, and the insert can have the wave shape perimeter shown in FIGS. 1-5. The wave shaped perimeter simulates the effect of the presence of the next surrounding ring of cells on the fluid flow within the production module.

In one embodiment, the various plastic components are connected using laser welding. Alternately, press-fitting or epoxy or glues can be used.

In one embodiment, wires are connected to portions of the battery cells extending through an end plate, without the need for a wiring box. This embodiment can be used for cells cooled with a cooling plate, instead of direct fluid cooling. In an embodiment using the wiring box, a solid cover can be used to seal the ends of the fixture outside of the connections. The end caps have vents in one embodiment, allowing the venting of gasses expelled from a failing battery cell during thermal runaway.

In one embodiment, metal screws (e.g., aluminum) are imbedded in the end-caps, allowing a connection with the battery cells inside without using a wiring box and a notch for the wires. Wires can be attached to the screws outside the fixture. The screws can be screwed in after assembly until they make solid contact with the battery cells inside. Alternately, spring-loaded contacts can be used instead of screws, eliminating the need for manual adjustment.

In one embodiment, testing involves exciting the central battery cell to thermal runaway, and monitoring the temperature of neighboring cells. To simulate a worst case condition, fluid flow is stopped for the test, to simulate a failure of the fluid cooling system. Alternate tests can be done with fluid flowing. Also, battery cells near the edges, rather than the central battery cell, can be excited to thermal runaway, with the center battery cells and other battery cells being monitored.

### Cooling Plate Embodiment

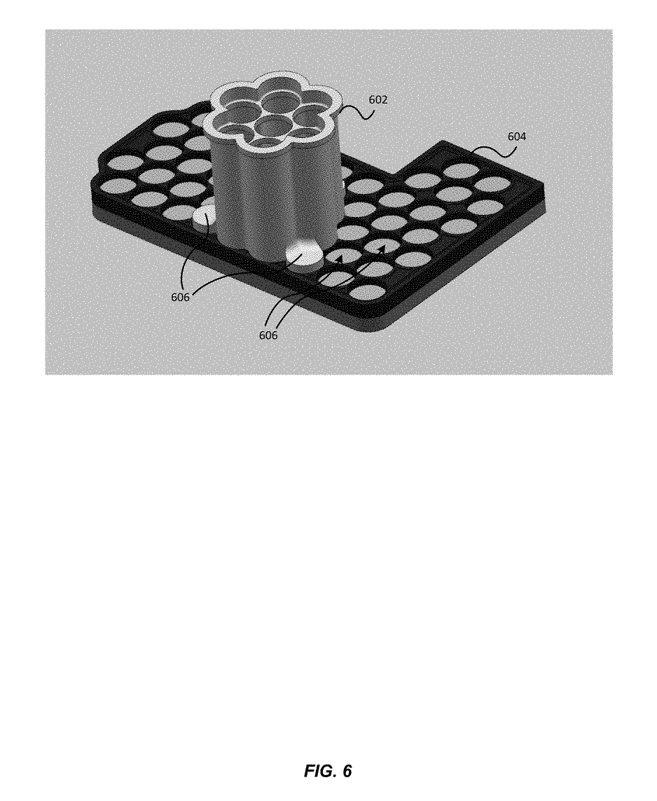

FIG. 6 shows an embodiment of a test fixture 602 which uses a cooling plate 604 instead of being directly fluid cooled. Cooling plate 604 has a number of depressions or holes 606 which are spaced to engage the ends of cylindrical battery cells inside test fixture 602, simulating the cooling plate of a production model. The test fixture is anchored to cooling plate 604 with tabs 606 which engage certain ones of holes 606.

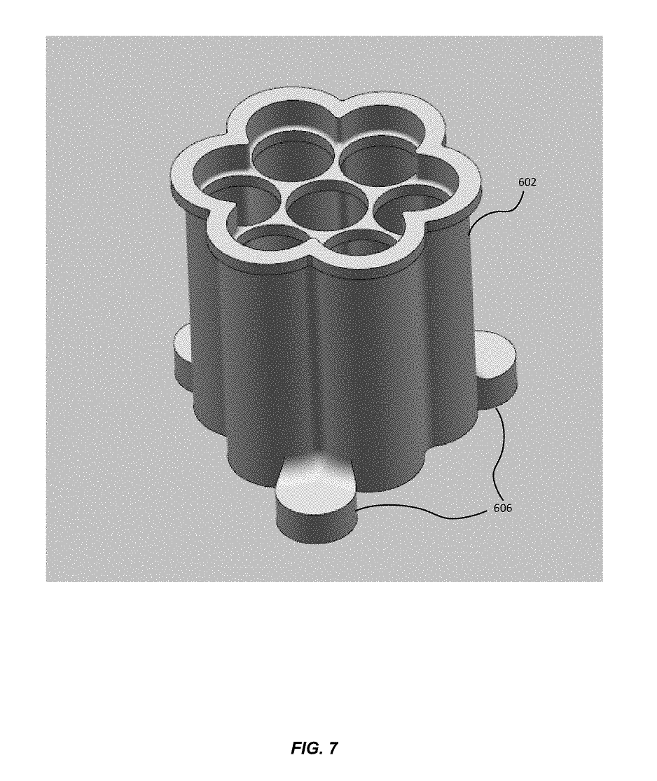

FIG. 7 shows an embodiment of the test fixture 602 of FIG. 6 before attachment to the cooling plate. The same or similar thermal runaway tests to those used for the fluid filled test fixture can be performed. The cooling plate can be controlled to simulate failure of the cooling plate in a production module.

### Cell-Simulating Plus Embodiment

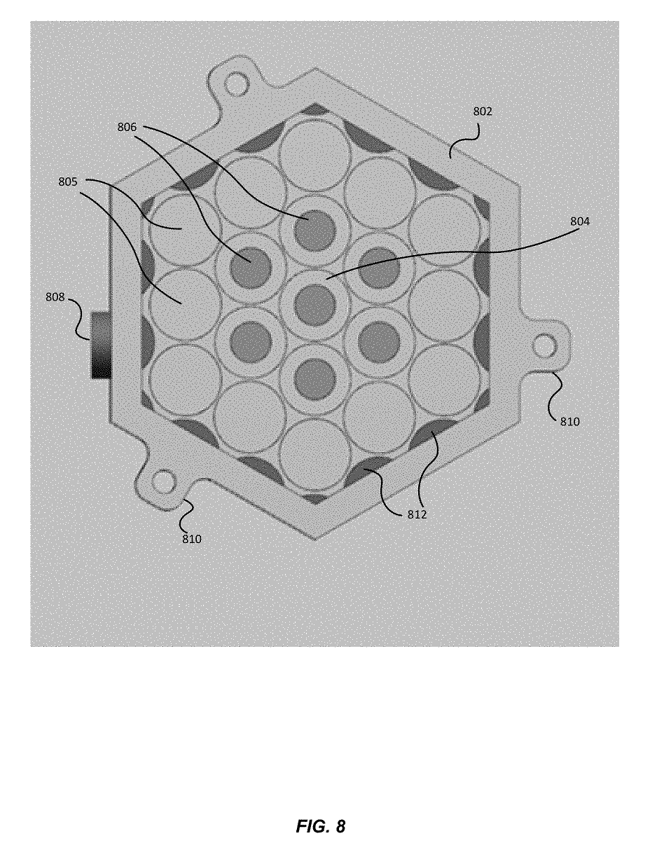

FIG. 8 shows a top view of an embodiment of a fluid filled test fixture 802 including an outer ring of plugs instead of battery cells, showing the battery cells and plugs inside the test fixture. A central battery cell 804 is surrounded by six battery cells 806. To simulate an additional ring of battery cells, without using more actual battery cells, a ring of twelve plugs 805 is added. In one embodiment, the plugs are made of material which has similar heat transfer characteristics to a battery cell, such as aluminum.

Also shown is a fluid inlet 808 and several tabs 810 for securing the plates of the fixture to the fixture housing. The inside of fixture 802 has curved, semi-circular wall elements 812, to simulate another ring of battery cells. In particular, elements 812 help provide a fluid flow similar to an actual production battery module.

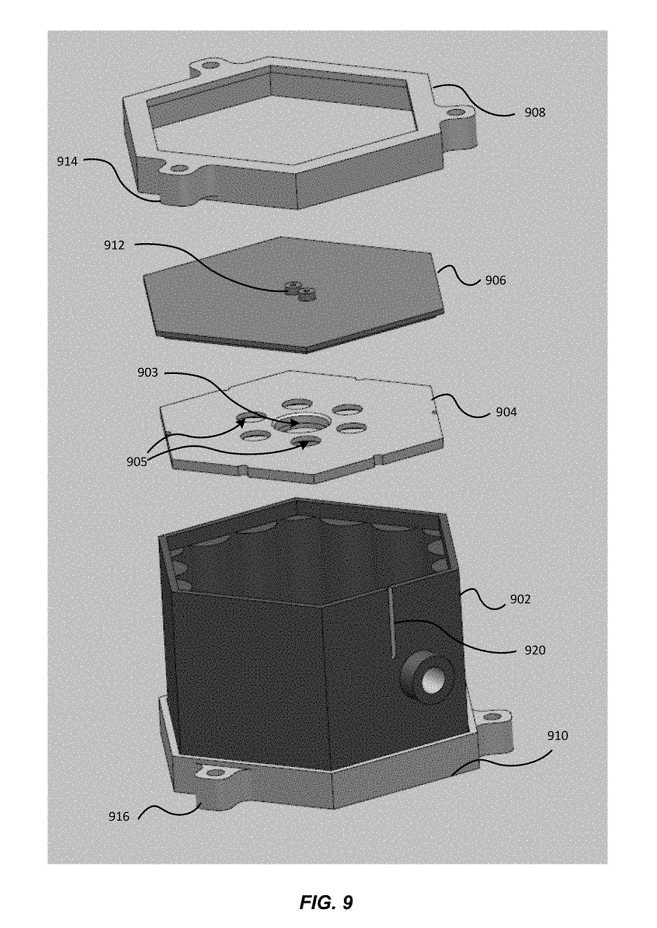

FIG. 9 is an exploded perspective view of the test fixture in the embodiment of FIG. 8. Housing 902 holds the battery cells and plugs. An inner end plate 904 has a hole 903 for allowing electrical and thermocouple access to the center battery cell, and a number of smaller holes 905 for access to the surrounding battery cells. Center hole 903 is larger to allow electrical contact with both the positive and negative screws.

An end plate 906 seals over plate 904. Upon an explosion or other failure of the center cell, and possibly other cells, plastic plate 905 may be broken or otherwise compromised. Plate 906 insures that the fluid does not escape the test fixture, and thus maintains a proper simulation of a production module. Plate 906 could be burned through during a thermal runaway. It is provided to properly simulate the module environment. Plugs 912 in plate 906 provide access for the screws that make electrical contact with the initiator cell. Retaining element 908 holds plate 906 in place. Tabs 914 have openings for insertion of a bolt to also go through openings in tabs 916 in a bottom retaining element 910 to hold the assembly in place. A nut is attached to the end of the bolt and tightened. Slot 920 provides a gap for routing thermocouple wire leads.

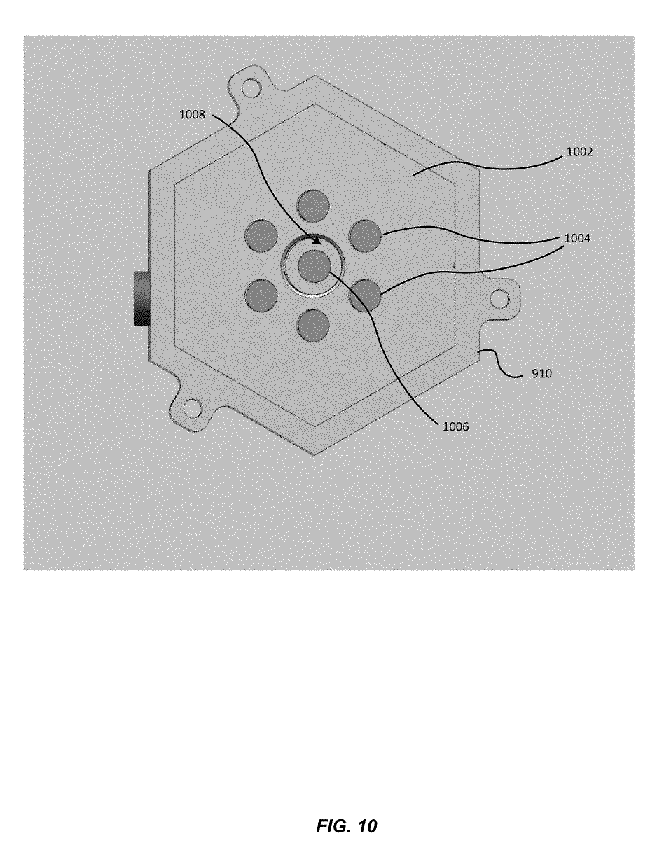

FIG. 10 is a top view of one embodiment only partially assembled to show an interior plate 1002 of the test fixture of FIG. 9, inside bottom retaining element 910 of FIG. 9. The ends of surrounding battery cells 1004 are exposed through holes for cell venting. Central battery cell 1006 is also exposed, with a wider area 1008 of the battery cell exposed to allow for electrical contact from the cell to the aluminum screws.

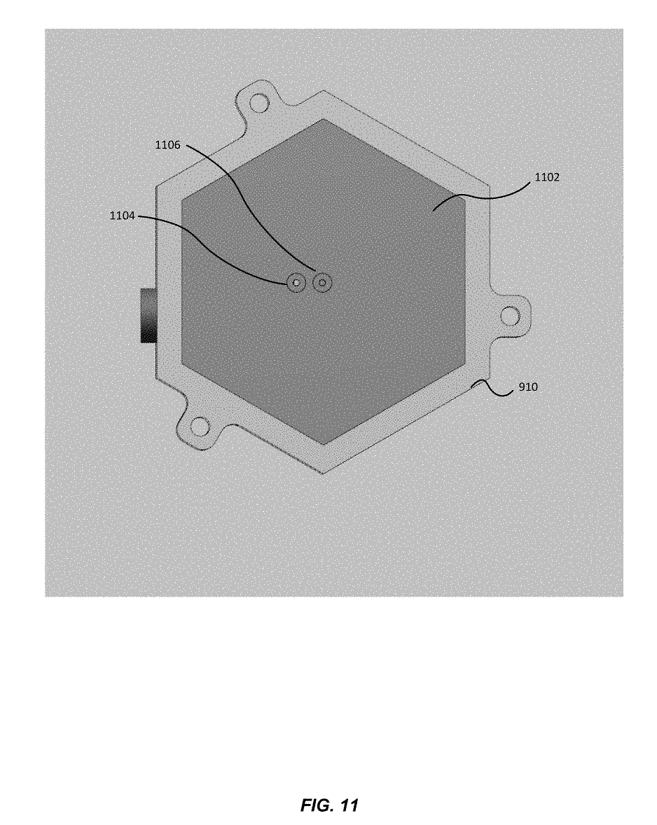

FIG. 11 is a bottom view of the embodiment of FIG. 10 showing an exterior end cap 1102 of the test fixture of FIG. 9, mounted over the interior plate 1002 of FIG. 10. A pair of through-holes 1104 and 1106 are shown. Both are for the aluminum screws to make contact with the positive cell cap (center) and negative cell can (off-center).

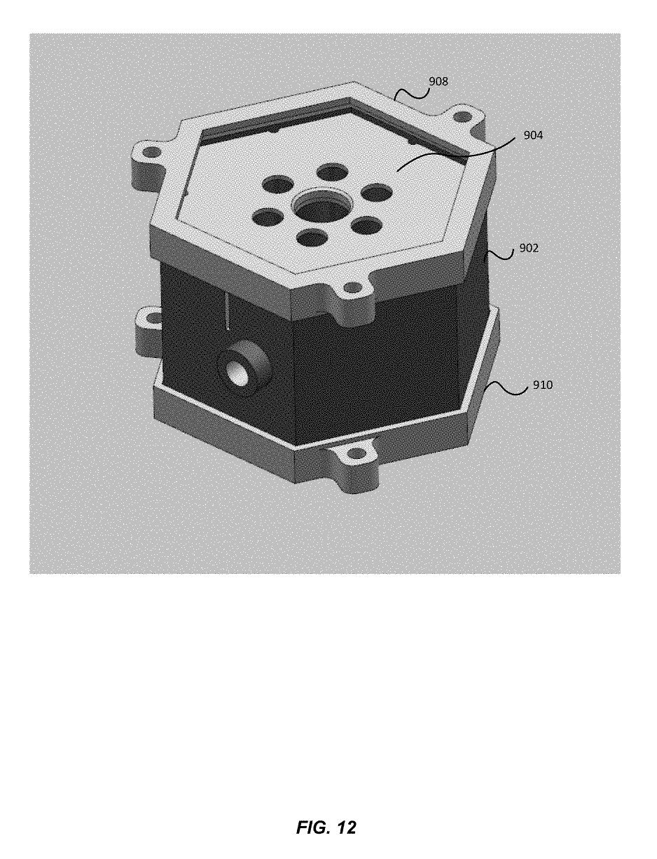

FIG. 12 is a perspective view of an assembled test fixture of the embodiment of FIG. 9, with top end cap 906 removed to show the interior plate 904.

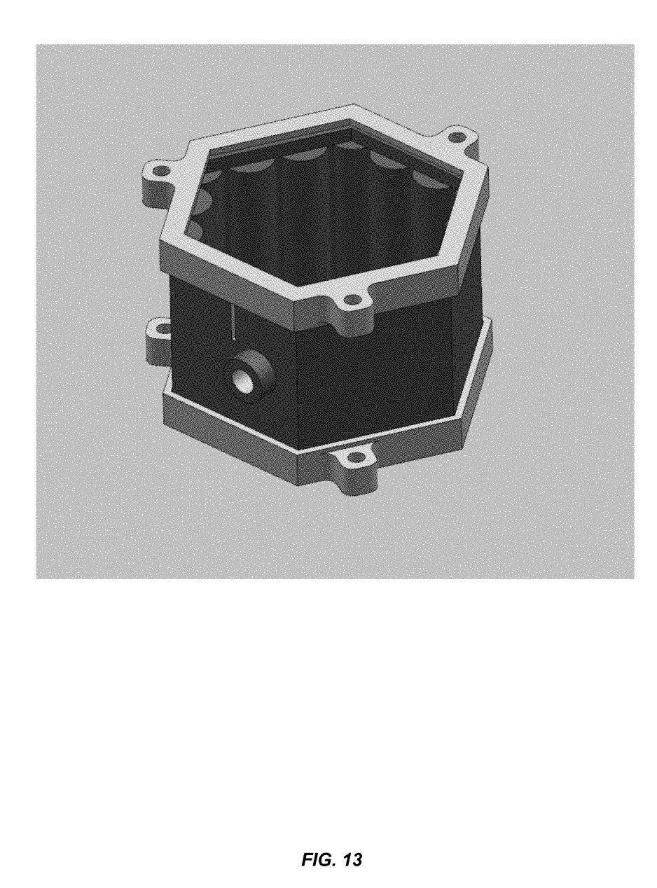

FIG. 13 is a perspective view of the assembled test fixture of the embodiment of FIG. 12 before inserting the battery cells and end plates.

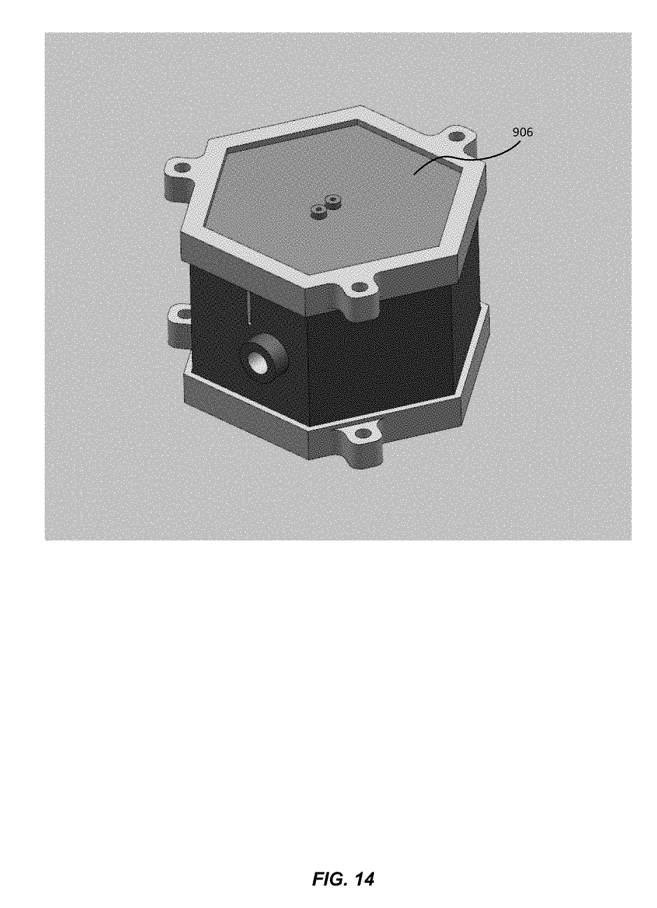

FIG. 14 is a perspective view of the assembled test fixture of the embodiment of FIG. 12 with the exterior end cap 906 added.

The aluminum plugs in the embodiment of FIGS. 9-16 provide more accurate test results since they more accurately simulate the thermal characteristics of another ring of battery cells. Also, the plug cylinders allow a more accurate simulation of the fluid flow through a production module. In addition to placing thermocouples on the battery cells, thermocouples are attached to at least some of the aluminum plugs to monitor how their temperature is affected by the thermal runaway of the central battery cell.

Various modifications and different embodiments can be implemented. For example, other housing shapes than the cylindrical, undulating or hexagonal shapes shown above can be used, such as a shape with less than 6 sides, or more than 6 sides. The interior undulating wall of the housing can be formed with an insert, such as a plastic insert in a metal housing. The test modules can be attached end-to-end, rather than with an internal separating plate, to simulate clusters of battery cells in series in a production module. Instead of fluid inlets and outlets, air inlets and outlets can be provided for air-cooled module simulation.

In one embodiment, instead of wire sensor connections, miniature wireless transmitter chips can be attached to the battery cell sensors inside the module. The transmitters can transmit readings to external receivers. This eliminates the need to provide and seal a route for wiring.

### Tester Electronics

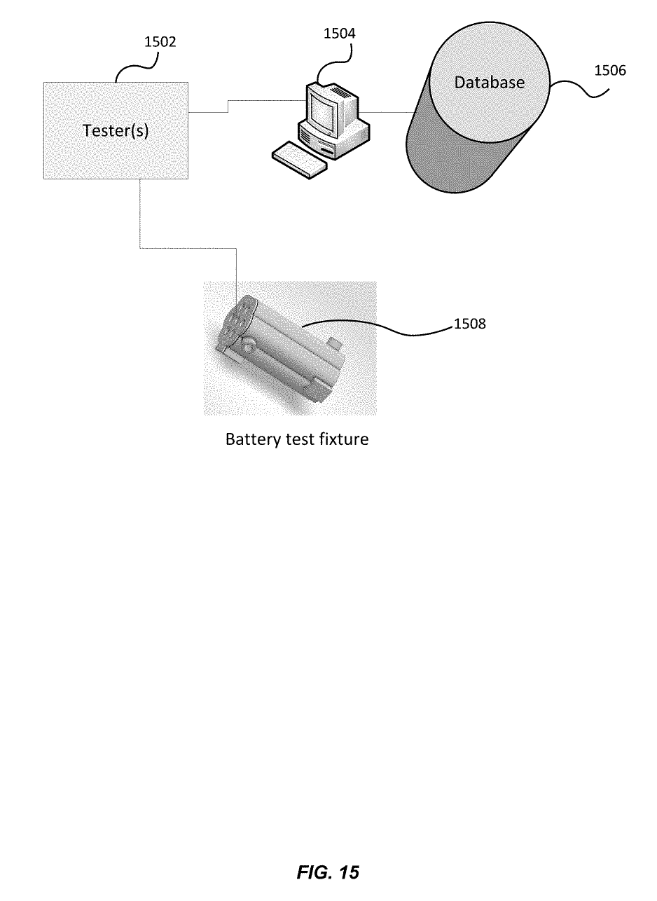

FIG. 15 shows an embodiment of an electronic testing system for the test fixture of the present invention. A tester 1502 is controlled by a computer 1504 having a processor and other circuitry. The computer 1504 operates under control of a program memory, using test sequences stored in a database 1506. Resulting test data is also stored in database 1506, or a separate database. Battery cell test fixture 1508 is connected to, and mounted in, tester 1502.

### Computer System

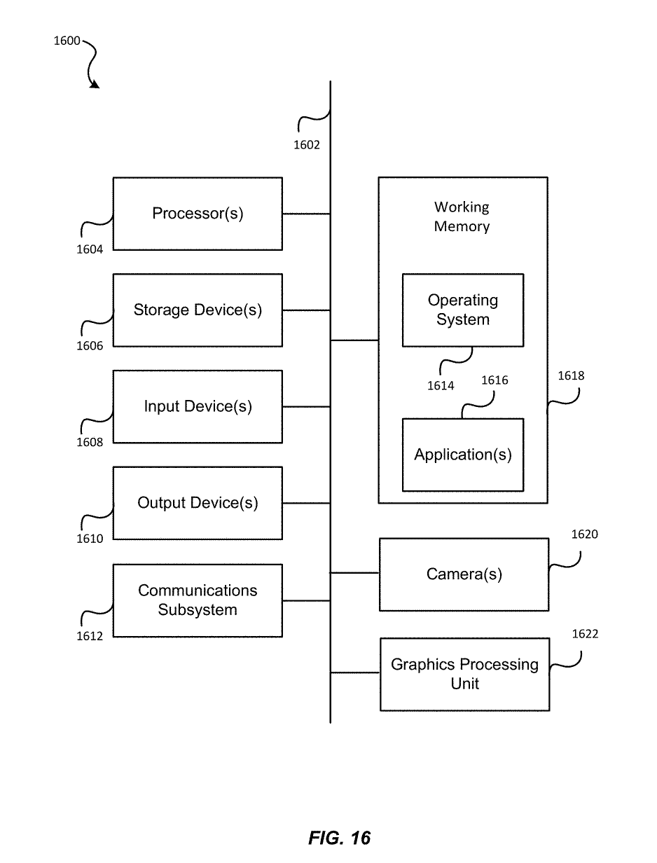

FIG. 16 illustrates an example of a computing system in which one or more implementations may be implemented. A computer system as illustrated in FIG. 16 may be incorporated as part of the above described computer 1504. For example, computer system 1600 can represent some of the components of a display, a computing device, a server, a desktop, a workstation, a control or interaction system in an automobile, a tablet, a netbook any other suitable computing system. A computing device may be any computing device with an image capture device or input sensory unit and a user output device. An image capture device or input sensory unit may be a camera device. A user output device may be a display unit. FIG. 16 provides a schematic illustration of one implementation of a computer system 1600 that can perform the methods provided by various other implementations, as described herein, and/or can function as the host computer system, a tablet computer and/or a computer system. FIG. 16 is meant only to provide a generalized illustration of various components, any or all of which may be utilized as appropriate. FIG. 16, therefore, broadly illustrates how individual system elements may be implemented in a relatively separated or relatively more integrated manner.

The computer system 1600 is shown comprising hardware elements that can be electrically coupled via a bus 1602 (or may otherwise be in communication, as appropriate). The hardware elements may include one or more processors 1604, including without limitation one or more general-purpose processors and/or one or more special-purpose processors (such as digital signal processing chips, graphics processing units 1622, and/or the like); one or more input devices 1608, which can include without limitation one or more cameras, sensors, a mouse, a keyboard, a microphone, and/or the like; and one or more output devices 1610, which can include without limitation a display unit. Additional cameras 1620 may be employed for detection of items such as bar codes. In some implementations, input devices 1608 may include one or more sensors such as infrared, depth, and/or ultrasound sensors.

In some implementations of the implementations of the invention, various input devices 1608 and output devices 1610 may be embedded into interfaces such as display devices, tables, floors, walls, and window screens. Furthermore, input devices 1608 and output devices 1610 coupled to the processors may form multi-dimensional tracking systems.

The computer system 1600 may further include (and/or be in communication with) one or more non-transitory storage devices 1606, which can comprise, without limitation, local and/or network accessible storage, and/or can include, without limitation, a disk drive, a drive array, an optical storage device, a solid-state storage device such as a random access memory (“RAM”) and/or a read-only memory (“ROM”), which can be programmable, flash-updateable and/or the like. Such storage devices may be configured to implement any appropriate data, storage, including without limitation, various file systems, database structures, and/or the like.

The computer system 1600 might also include a communications subsystem 1612, which can include without limitation a modem, a network card (wireless or wired), an infrared communication device, a wireless communication device and/or chipset (such as a Bluetooth device, an 802.11 device, a Wi-Fi device, a WiMax device, cellular communication facilities, etc.), and/or the like. The communications subsystem 512 may permit data to be exchanged with a network, other computer systems, and/or any other devices described herein. In many implementations, the computer system 500 will further comprise a non-transitory working memory 1618, which can include a RAM or ROM device, as described above.

The computer system 1600 also can comprise software elements, shown as being currently located within the working memory 1618, including an operating system 1614, device drivers, executable libraries, and/or other code, such as one or more application programs 1616, which may comprise computer programs provided by various implementations, and/or may be designed to implement methods, and/or configure systems, provided by other implementations, as described herein. Merely by way of example, one or more procedures described with respect to the method(s) discussed above might be implemented as code and/or instructions executable by a computer (and/or a processor within a computer); in an aspect, then, such code and/or instructions can be used to configure and/or adapt a general purpose computer (or other device) to perform one or more operations in accordance with the described methods.

A set of these instructions and/or code might be stored on a computer-readable storage medium, such as the storage device(s) 1606 described above. In some cases, the storage medium might be incorporated within a computer system, such as computer system 500. In other implementations, the storage medium might be separate from a computer system (e.g., a removable medium, such as a compact disc), and/or provided in an installation package, such that the storage medium can be used to program, configure and/or adapt a general purpose computer with the instructions/code stored thereon. These instructions might take the form of executable code, which may be executable by the computer system 1600 and/or might take the form of source and/or installable code, which, upon compilation and/or installation on the computer system 1600 (e.g., using any of a variety of generally available compilers, installation programs, compression/decompression utilities, etc.) then takes the form of executable code.

Substantial variations may he made in accordance with specific requirements. For example, customized hardware might also be used, and/or particular elements might be implemented in hardware, software (including portable software, such as applets, etc.), or both. Further, connection to other computing devices such as network input/output devices may he employed. In some implementations, one or more elements of the computer system 1600 may be omitted or may be implemented separate from the illustrated system. For example, the processor 1604 and/or other elements may be implemented separate from the input device 1608. In one implementation, the processor may be configured to receive images from one or more cameras that are separately implemented. In some implementations, elements in addition to those illustrated in FIG. 16 may be included in the computer system 1600.

Some implementations may employ a computer system (such as the computer system 1600) to perform methods in accordance with the disclosure. For example, some or all of the procedures of the described methods may be performed by the computer system 1600 in response to processor 1604 executing one or more sequences of one or more instructions (which might be incorporated into the operating system 1614 and/or other code, such as an application program 1616) contained in the working memory 1618. Such instructions may be read into the working memory 1618 from another computer-readable medium, such as one or more of the storage device(s) 1606. Merely by way of example, execution of the sequences of instructions contained in the working memory 1618 might cause the processor(s) 1604 to perform one or more procedures of the methods described herein.

The terms “machine-readable medium” and “computer-readable medium,” as used herein, refer to any medium that participates in providing data that causes a machine to operate in a specific fashion. In some implementations implemented using the computer system 1600, various computer-readable media might be involved in providing instructions/code to processor(s) 1604 for execution and/or might be used to store and/or carry such instructions/code (e.g., as signals). In many implementations, a computer-readable medium may be a physical and/or tangible storage medium. Such a medium may take many forms, including but not limited to, non-volatile media, volatile media, and transmission media. Non-volatile media include, for example, optical and/or magnetic disks, such as the storage device(s) 1606. Volatile media include, without limitation, dynamic memory, such as the working memory 1618. Transmission media include, without limitation, coaxial cables, copper wire and fiber optics, including the wires that comprise the bus 1602, as well as the various components of the communications subsystem 1612 (and/or the media by which the communications subsystem 1612 provides communication with other devices). Hence, transmission media can also take the form of waves (including without limitation radio, acoustic and/or light waves, such as those generated during radio-wave and infrared data communications).

Common forms of physical and/or tangible computer-readable media include, for example, a floppy disk, a flexible disk, hard disk, magnetic tape, or any other magnetic medium, a CD-ROM, any other optical medium, punch cards, paper tape, any other physical medium with patterns of holes, a RAM, a PROM, EPROM, a FLASH-EPROM, any other memory chip or cartridge, a carrier wave as described hereinafter, or any other medium from which a computer can read instructions and/or code.

Various forms of computer-readable media may be involved in carrying one or more sequences of one or more instructions to the processor(s) 1604 for execution. Merely by way of example, the instructions may initially be carried on a magnetic disk and/or optical disc of a remote computer. A remote computer might load the instructions into its dynamic memory and send the instructions as signals over a transmission medium to be received and/or executed by the computer system 500. These signals, which might be in the form of electromagnetic signals, acoustic signals, optical signals and/or the like, are all examples of carrier waves on which instructions can be encoded, in accordance with various implementations of the invention.

The communications subsystem 1612 (and/or components thereof) generally will receive the signals, and the bus 1602 then might carry the signals (and/or the data, instructions, etc. carried by the signals) to the working memory 1618, from which the processor(s) 1604 retrieves and executes the instructions. The instructions received by the working memory 1618 may optionally be stored on a non-transitory storage device 1606 either before or after execution by the processor(s) 1604.

It is understood that the specific order or hierarchy of steps in the processes disclosed is an illustration of exemplary approaches. Based upon design preferences, it is understood that the specific order or hierarchy of steps in the processes may be rearranged. Further, some steps may be combined or omitted. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Moreover, nothing disclosed herein is intended to be dedicated to the public.

While some examples of methods and systems herein are described in terms of software executing on various machines, the methods and systems may also be implemented as specifically-configured hardware, such as field-programmable gate array (FPGA) specifically to execute the various methods. For example, examples can be implemented in digital electronic circuitry, or in computer hardware, firmware, software, or in a combination thereof. In one example, a device may include a processor or processors. The processor comprises a computer-readable medium, such as a random access memory (RAM) coupled to the processor. The processor executes computer-executable program instructions stored in memory, such as executing one or more computer programs. Such processors may comprise a microprocessor, a digital signal processor (DSP), an application-specific integrated circuit (ASIC), field programmable gate arrays (FPGAs), and state machines. Such processors may further comprise programmable electronic devices such as PLCs, progammable interrupt controllers (PICs), programmable logic devices (PLDs), progammable read-only memories (PROMs), electronically programmable read-only memories (EPROMs ter EEPROMs), or other similar devices.

Such processors may comprise, or may be in communication with, media, for example computer-readable storage media, that may store instructions that, when executed by the processor, can cause the processor to perform the steps described herein as carried out, or assisted, by a processor. Examples of computer-readable media may include, but are not limited to, an electronic, optical, magnetic, or other storage device capable of providing a processor, such as the processor in a web server, with computer-readable instructions. Other examples of media comprise, but are not limited to, a floppy disk. CD-ROM, magnetic disk, memory chip, ROM, RAM, ASIC, configured processor, all optical media, all magnetic tape or other magnetic media, or any other medium from which a computer processor can read. The processor, and the processing, described may be in one or more structures, and may be dispersed through one or more structures. The processor may comprise code for carrying out one or more of the methods (or parts of methods) described herein.

The foregoing description of some examples has been presented only for the purpose of illustration and description and is not intended to be exhaustive or to limit the disclosure to the precise forms disclosed. Numerous modifications and adaptations thereof will be apparent to those skilled in the art without departing from the spirit and scope of the disclosure.

Reference herein to an example or implementation means that a particular feature, structure, operation, or other characteristic described in connection with the example may be included in at least one implementation of the disclosure. The disclosure is not restricted to the particular examples or implementations described as such. The appearance of the phrases “in one example,” “in an example,” “in one implementation,” or “in an implementation,” or variations of the same in various places in the specification does not necessarily refer to the same example or implementation. Any particular feature, structure, operation, or other characteristic described in this specification in relation to one example or implementation may be combined with other features, structures, operations, or other characteristics described in respect of any other example or implementation.

Use herein of the word “or” is intended to cover inclusive and exclusive OR conditions. In other words, A or B or C includes any or all of the following alternative combinations as appropriate for a particular usage: A alone; B alone; C alone; A and B only; A and C only; B and C only; and A and B and C.

What is claimed is:

1. A battery cell testing fixture comprising:
a first test housing shaped to hold a plurality of battery cells including a central battery cell and a plurality of surrounding battery cells;
wherein the first test housing holds the plurality of battery cells in a desired proximity corresponding to an actual proximity in a production battery cell module containing a larger number of battery cells;
at least one battery test initiation lead element configured to he engaged to the central battery cell; and
at least one battery test monitoring lead element configured to be engaged to one of the plurality of surrounding battery cells.

2. The battery cell testing fixture of claim 1, wherein the first test housing comprises:
an endplate portion having depressions for engaging ends of the plurality of batters cells and maintaining the plurality of batters cells in the desired proximity.

3. The battery cell testing fixture of claim 1, wherein the first test housing comprises:
a fluid inlet port; and
a fluid outlet port.

4. The battery cell testing fixture of claim 3 wherein
the fluid inlet port is proximate a first end of the first test housing; and
the fluid outlet port is proximate a second end of the first test housing.

5. The battery cell testing fixture of claim 1 wherein the first test housing is configured to be sealed to hold a fluid during testing.

6. The battery cell testing fixture of claim 1 wherein the battery test monitoring lead element comprises a thermocouple.

7. The battery cell testing fixture of claim 1, wherein the first test housing further comprises:
at least two seating tabs positioned at the end of the first test housing for engaging one or more seating slots in a cooling plate.

8. The battery cell testing fixture of claim 1 further comprising:
an endplate portion with openings to expose ends of the plurality of battery cells and allow connections to the battery test initiation lead and the battery test monitoring lead.

9. The battery cell testing fixture of claim 8 wherein at least one of the openings is sufficiently large to expose hot a positive and a negative contact on the battery cell.

10. The battery cell testing fixture of claim 1 further comprising:
a second test housing shaped to hold a second central battery cell and a second plurality of surrounding battery cells; and
the second test housing having an end adjacent an end of the first test housing.

11. The battery cell testing fixture of claim 10 wherein the second test housing is a second portion of the first test housing.

12. The battery cell testing fixture of claim 1, wherein: the first test housing is further shaped to hold a plurality of battery cell shaped plugs around the plurality of surrounding battery cells.

13. The battery cell testing fixture of claim 10 wherein the first test housing holds 6 surrounding battery cells and 12 battery cell shaped plugs.

14. The battery cell testing fixture of claim 1 wherein the first test housing has a thermal transfer characteristic that mimics the thermal transfer characteristic of surrounding battery cells in the production battery cell module.

15. The battery cell testing fixture of claim 1 wherein the first test housing is metal, and further comprising a plastic insert mounted between the battery cells and an interior wall of the metal test housing.

16. The battery cell testing fixture of claim 1 further comprising:
an interior end plate for securing the battery cells in place, with openings for exposing ends of the battery cells for contact with the battery test initiation lead element and battery test lead monitoring element; and
an exterior end cap mounted outside the interior end plate.

17. A method for testing battery cells simulating an environment with a larger number of battery cells, comprising:
providing a first test housing shaped to hold a plurality of battery cells, including a central battery cell and a plurality of surrounding battery cells, wherein the first test housing holds the plurality of battery cells in a desired proximity corresponding to an actual proximity in a production battery cell module containing a larger number of battery cells;
engaging at least one battery test initiation lead element to the central battery cell;
engaging at least one battery test monitoring lead and a thermocouple to one of the plurality of surrounding battery cells;
attaching a battery tester to the battery test initiation lead element and the battery test monitoring lead;
applying an excitation to the battery test initiation lead element to initiate a thermal runaway in the central battery cell; and
monitoring an effect on the surrounding battery cells from the battery test monitoring lead.

18. The method of claim 17 further comprising:
providing a fluid inlet port;
providing a fluid outlet port; and
pumping a fluid into the fluid input port and out of the fluid outlet port.

19. The method of claim 18 further comprising stopping the pumping of the fluid and applying the excitation without the flow of fluid.

20. A battery cell testing fixture comprising:
a first test housing shaped to hold a plurality of battery cells including a central battery cell and a plurality of surrounding battery cells;
wherein the first test housing holds the plurality of battery cells in a desired proximity corresponding to an actual proximity in a production battery cell module containing a larger number of battery cells;
at least one battery test initiation lead element configured to be engaged to the central battery cell; and
at least one thermocouple engaged to one of the plurality of surrounding battery cells;
an endplate portion having depressions for engaging ends of the plurality of battery cells and maintaining the plurality of battery cells in the desired proximity;
a fluid inlet port proximate a first end of the first test housing; and
a fluid outlet port proximate a second end of the first test housing; and.
wherein the first test housing is configured to be sealed to hold a fluid during testing.
